(19) United States
(12) Patent Application Publication
(10) Pub. No.: US 2004/0119146 A1
(43) Pub. Date: Jun. 24, 2004

(54) Semiconductor device and method of manufacturing the same, circuit board, and electronic instrument

(75) Inventor: Hiroshi Masuya, Tsuruoka-shi (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/664,585

(22) Filed: Sep. 17, 2003

(30) Foreign Application Priority Data
Sep. 26, 2002 (JP) 2002-281082

(51) Int. Cl. H01L 23/495

(52) U.S. Cl. 257/666

(57) ABSTRACT

A semiconductor device including: an inner lead having a sloping section sloping upward and outward; a die pad; a semiconductor chip having an electrode and bonded to the die pad; a wire electrically connecting the inner lead to the electrode; a sealing section sealing the inner lead, the semiconductor chip, and the wire; and an outer lead extending outward from the sealing section.

Japanese Patent Application No. 2002-281082, filed on Sep. 26, 2002, is hereby incorporated by reference in its entirety.

### BACKGROUND OF THE INVENTION

The present invention relates to a semiconductor device, a method of manufacturing the same, a circuit board, and an electronic instrument.

In the manufacture of a semiconductor device, an electrode of a semiconductor chip is electrically connected with an inner lead through a wire. In this case, the wire has to be connected only to a target inner lead to prevent a short circuit between the wire and other inner leads.

### BRIEF SUMMARY OF THE INVENTION

According to one aspect of the present invention, there is provided a semiconductor device comprising:

an inner lead having a sloping section sloping upward and outward;

a die pad;

a semiconductor chip having an electrode and bonded to the die pad;

a wire electrically connecting the inner lead to the electrode;

a sealing section sealing the inner lead, the semiconductor chip, and the wire; and

an outer lead extending outward from the sealing section.

According to another aspect of the present invention, there is provided a circuit board on which the above semiconductor device is mounted.

According to a further aspect of the present invention, there is provided an electronic instrument comprising the above semiconductor device.

According to still another aspect of the present invention, there is provided a method of manufacturing a semiconductor device, the method comprising:

forming a sloping section sloping upward and outward by bending an inner lead of a lead frame;

bonding a semiconductor chip having an electrode to a die pad of the lead frame;

electrically connecting the inner lead to the electrode through a wire; and

sealing the inner lead, the semiconductor chip, and the wire.

### BRIEF DESCRIPTION OF THE SEVERAL VIEWS OF THE DRAWING

FIG. 1 is a view showing a semiconductor device according to one embodiment of the present invention.

FIG. 2 is a view showing a method of manufacturing a semiconductor device according to one embodiment of the present invention.

FIG. 3 is a view showing a method of manufacturing a semiconductor device according to one embodiment of the present invention.

FIG. 4 is a view showing a circuit board on which a semiconductor device according to one embodiment of the present invention is mounted.

FIG. 5 is a view showing an electronic instrument including a semiconductor device according to one embodiment of the present invention.

FIG. 6 is a view showing another electronic instrument including a semiconductor device according to one embodiment of the present invention.

FIG. 7 is a view showing a modification example of a semiconductor device according to one embodiment of the present invention.

FIGS. 8A and 8B are views showing a method of manufacturing a semiconductor device according to a modification of one embodiment of the present invention.

FIG. 9 is a view showing a modification example of a semiconductor device according to one embodiment of the present invention.

### DETAILED DESCRIPTION OF THE EMBODIMENT

Embodiments of the present invention may provide a highly reliable semiconductor device in which a short circuit between a bonding wire and an inner lead rarely occurs, a method of manufacturing such a semiconductor device, a circuit board, and an electronic instrument.

(1) According to one embodiment of the present invention, there is provided a semiconductor device, comprising:

an inner lead having a sloping section sloping upward and outward;

a die pad;

a semiconductor chip having an electrode and bonded to the die pad;

a wire electrically connecting the inner lead to the electrode;

a sealing section sealing the inner lead, the semiconductor chip, and the wire; and

an outer lead extending outward from the sealing section.

In this semiconductor device, the height of the end of the inner lead is lowered. This enables provision of a highly reliable semiconductor device in which the wire connecting the electrode of the semiconductor chip to the inner lead rarely comes in contact with an inner lead other than the target inner lead.

(2) In this semiconductor device, the wire may be bonded to the sloping section.

(3) In this semiconductor device, the inner lead may further have an end section extending inward from a lower end of the sloping section in a horizontal direction.

(4) In this semiconductor device, the wire may be bonded to the end section.

(5) In this semiconductor device, the inner lead may further have a second sloping section sloping downward and outward from a higher end of the sloping section.

(6) In this semiconductor device, the inner lead may further have a portion extending in a horizontal direction and connected to the outer lead.

(7) In this semiconductor device, a bonding position between the wire and the inner lead may be lower than the position of the electrode.

(8) In this semiconductor device, a surface of the die pad opposite to the semiconductor chip may be exposed from the sealing section.

(9) According to one embodiment of the present invention, there is provided a circuit board on which the above semiconductor device is mounted.

(10) According to one embodiment of the present invention, there is provided an electronic instrument comprising the above semiconductor device.

(11) According to one embodiment of the present invention, there is provided a method of manufacturing a semiconductor device, the method comprising:

forming a sloping section sloping upward and outward by bending an inner lead of a lead frame;

bonding a semiconductor chip having an electrode to a die pad of the lead frame;

electrically connecting the inner lead to the electrode through a wire; and

sealing the inner lead, the semiconductor chip, and the wire.

According to this method of manufacturing a semiconductor device, the height of the end of the inner lead is lowered. Therefore, it becomes difficult for the wire connecting the electrode of the semiconductor chip to the inner lead to come in contact with an inner lead other than the target inner lead, and a highly reliable semiconductor device can be manufactured.

(12) In this method of manufacturing a semiconductor device, the wire may be bonded to the sloping section.

(13) This method of manufacturing a semiconductor device may further comprise forming an end section extending inward from a lower end of the sloping section in a horizontal direction by bending the inner lead.

(14) In this method of manufacturing a semiconductor device, the wire may be bonded to the end section.

(15) This method of manufacturing a semiconductor device may further comprise forming a second sloping section sloping downward and outward from a higher end of the sloping section by bending the inner lead.

(16) This method of manufacturing a semiconductor device may further comprise forming a portion extending in a horizontal direction and outward from a higher end of the sloping section and bonded to the outer lead of the lead frame.

(17) In this method of manufacturing a semiconductor device, a bonding position between the wire and the inner lead may be made to be lower than the position of the electrode.

(18) This method of manufacturing a semiconductor device may further comprise exposing a surface of the die pad opposite to the semiconductor chip from the sealing section.

The embodiments of the present invention are described below with reference to the drawings. However, the present invention is not limited to the following embodiments.

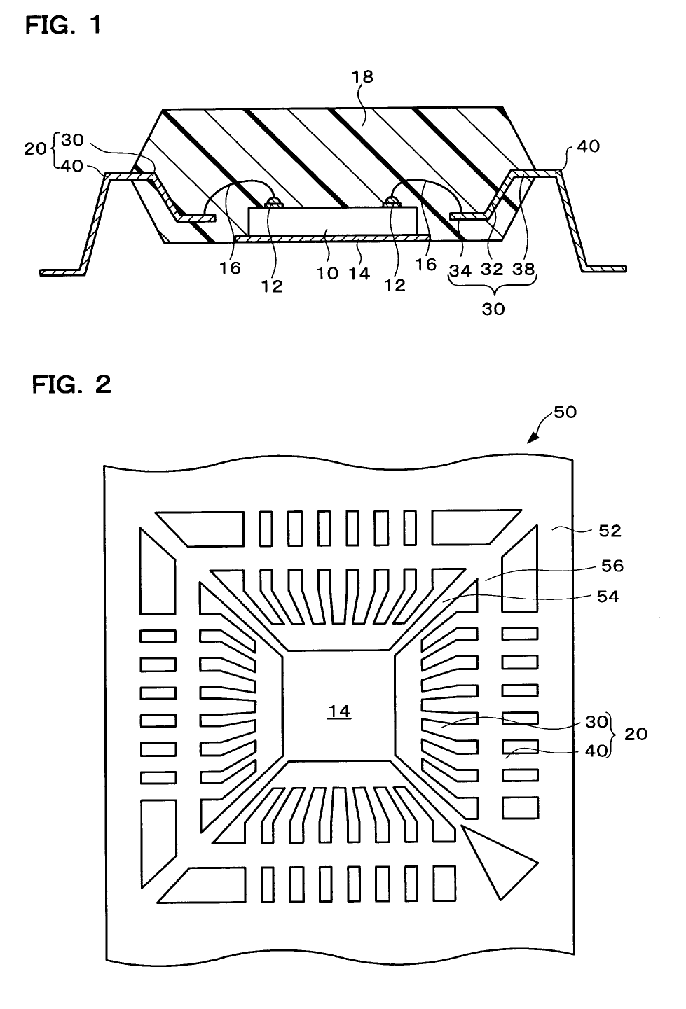

FIG. 1 is a cross-sectional view showing a semiconductor device according to one embodiment to which the present invention is applied. The semiconductor device according to this embodiment includes a semiconductor chip 10. The planar shape of the semiconductor chip 10 is generally rectangular.

A plurality of electrodes 12 are formed on one surface (active surface) of the semiconductor chip 10. The electrode 12 may be formed thin and flat on the semiconductor chip 10 using aluminum, copper, or the like. The planar shape of the electrodes 12 may be rectangular, circular, or the like. The electrodes 12 may be formed by forming a bump on a pad. In this case, the bump may be formed by electroless plating or may be a ball bump formed by wire bonding. Nickel, chromium, titanium, or the like may be provided between the pad and the bump as a diffusion prevention layer for a bump metal. The electrodes 12 may be arranged along at least one side (two parallel sides or four sides in many cases) of the active surface of the semiconductor chip 10. The electrodes 12 may be formed only on the end of the semiconductor chip 10 so as to avoid the center of the active surface of the semiconductor chip 10.

A passivation film (not shown) may be formed on the active surface of the semiconductor chip 10 so as to avoid at least a part of the electrodes 12. The passivation film may be formed of SiO₂, SiN, polyimide resin, or the like.

The semiconductor chip 10 may be bonded to a die pad 14. The die pad 14 may be downset. The surface of the die pad 14 opposite to the surface to which the semiconductor chip 10 is bonded may be exposed from a sealing section 18. The planar shape of the die pad 14 may be rectangular. The semiconductor chip 10 may be secured to the die pad 14 through an adhesive (not shown).

The semiconductor device according to this embodiment includes a plurality of leads 20. Each of the leads 20 includes an inner lead 30 and an outer lead 40. The inner lead 30 is a part which is sealed with the sealing section 18. The outer lead 40 is a part which is pulled out from the sealing section 18 and is used to electrically connect with the outside.

The inner lead 30 of the semiconductor device according to this embodiment includes a sloping section 32 which slopes upward toward the outside of the semiconductor device. As shown in FIG. 1, the end (end section 34) of the inner lead 30 may be disposed at a position lower than the base section of the inner lead 30. The inner lead 30 of the semiconductor device 1 shown in FIG. 1 includes a part 38 which extends from the outer lead 40 in the horizontal direction, and the end section 34 which extends from the sloping section 32 in the horizontal direction. The end section 34 may be disposed at a position lower than the electrode 12 of the semiconductor chip 10. The part 38 which extends in the horizontal direction may be disposed at a position higher than the top of the loop of the wire 16.

The semiconductor device according to this embodiment includes the wire 16 for electrically connecting the electrode 12 with the inner lead 30. The wire 16 may be bonded to the inner lead 30 at a position lower than the electrode 12 of the semiconductor chip 10. In other words, the bonding position of the wire 16 and the inner lead 30 may be lower than the electrode 12. The wire 16 may be bonded to the end section 34 of the inner lead 30 (see FIG. 1). The height of the loop of the wire 16 can be secured by allowing the bonding position of the wire 16 and the inner lead 30 to be lower than the electrode 12. Therefore, the wire 16 can be prevented from coming in contact with an inner lead other than the target inner lead, whereby a highly reliable semiconductor device can be provided. The bonding position of the wire 16 and the inner lead 30 may be lower than the surface (active surface) of the semiconductor chip 10 on which the electrode 12 is formed.

The semiconductor device according to this embodiment includes the sealing section 18. The inner leads 30, the semiconductor chip 10, and the wires 16 may be sealed with the sealing section 18. The die pad 14 may be sealed with the sealing section 18. The surface of the die pad 14 opposite to the surface to which the semiconductor chip 10 is bonded may be exposed. Moisture resistance and heat sink properties can be improved by exposing a part of the die pad 14, whereby a semiconductor device having higher reliability can be provided.

The semiconductor device according to this embodiment includes the outer lead 40 which extends outside the sealing section 18. The outer lead 40 is used to electrically connect with the outside.

The semiconductor device according to this embodiment has the above-described configuration. A method of manufacturing the semiconductor device is described below.

A lead frame 50 is provided (see FIG. 2). The lead frame 50 may be formed by processing a copper-based or iron-based sheet material. As the processing method, chemical etching or mechanical punching may be applied.

The lead frame 50 includes an outer frame 52. The outer frame 52 is generally rectangular. The outer frame 52 forms the outer shape of the lead frame 50. A jig hole (not shown) may be formed in the outer frame 52 so that a guide pin provided to a mold is inserted into the jig hole. This enables the lead frame 50 to be easily positioned in the mold.

The lead frame 50 includes the die pad 14. The die pad 14 is a portion on which an electronic part such as a semiconductor chip is mounted. The planar shape of the die pad 14 is often rectangular (or square in particular). The die pad 14 may be downset.

The lead frame 50 includes a tab suspension lead 54. The tab suspension lead 54 has a function of supporting the die pad 14 and may be connected with the corner of the die pad 14.

The lead frame 50 is provided with the plurality of leads 20. The leads 20 extend from the outer frame 52 toward the die pad 14. Each of the leads 20 includes the inner lead 30 and the outer lead 40. The inner lead 30 is a part which is sealed with the sealing section 18 of the semiconductor device. The outer lead 40 is a part which is pulled out from the sealing section 18 and is used to electrically connect with the outside.

The outer leads 40 extend from the outer frame 52 at right angles to each side of the rectangular die pad 14. The inner lead 30 extends from the outer lead 40 and slopes toward the center of the die pad 14. The adjacent leads 20 may be connected through a dam bar 56. In more detail, the dam bar 56 may connect the adjacent outer leads 40 in the area near the inner leads 30.

The sloping section 32 which slopes upward toward the outside of the semiconductor device is formed by bending the inner lead 30. The sloping section 32 may be formed by bending the inner lead 30 in the downset direction of the die pad 14. The position of the end of the inner lead 30 may be made lower than the position of the base section of the inner lead 30 by forming the sloping section 32. The part 38 which extends from the outer lead 40 in the horizontal direction and the sloping section 32 may be formed by bending the inner lead 30 in its middle. The inner lead 30 shown in FIG. 1 may be formed by forming the end section 34 by bending a part of the sloping section 32 in the direction opposite to the downset direction of the die pad 14. The inner lead 30 may be bent so that the end section 34 of the inner lead 30 is disposed at a position lower than the electrode 12 of the semiconductor chip 10.

The step of bending the inner lead 30 may be performed before, after, or at the same time as the step of downsetting the die pad 14. The inner lead 30 including the end section 34, the sloping section 32, and the part 38 which extends in the horizontal direction may be integrally formed by using a jig or the like.

The semiconductor chip 10 provided with the electrodes 12 is bonded to the die pad 14. The semiconductor chip 10 may be secured to the die pad 14 through an adhesive (not shown). As the adhesive, a thermosetting resin or a material having high thermal conductivity such as metal paste (silver paste, etc.) may be used. The step of bonding the semiconductor chip 10 may be performed before or after the step of downsetting the die pad 14. The step of bonding the semiconductor chip 10 may be performed before or after the step of bending the inner lead.

The inner lead 30 is electrically connected with the electrode 12 through the wire 16. The wire 16 may be formed by using a conventional bonding tool. The wire 16 may be bonded to the inner lead 30 at a position lower than the electrode 12. In other words, the bonding position of the wire 16 and the inner lead 30 may be lower than the electrode 12. As shown in FIG. 1, the wire 16 may be bonded to the end section 34 of the inner lead 30.

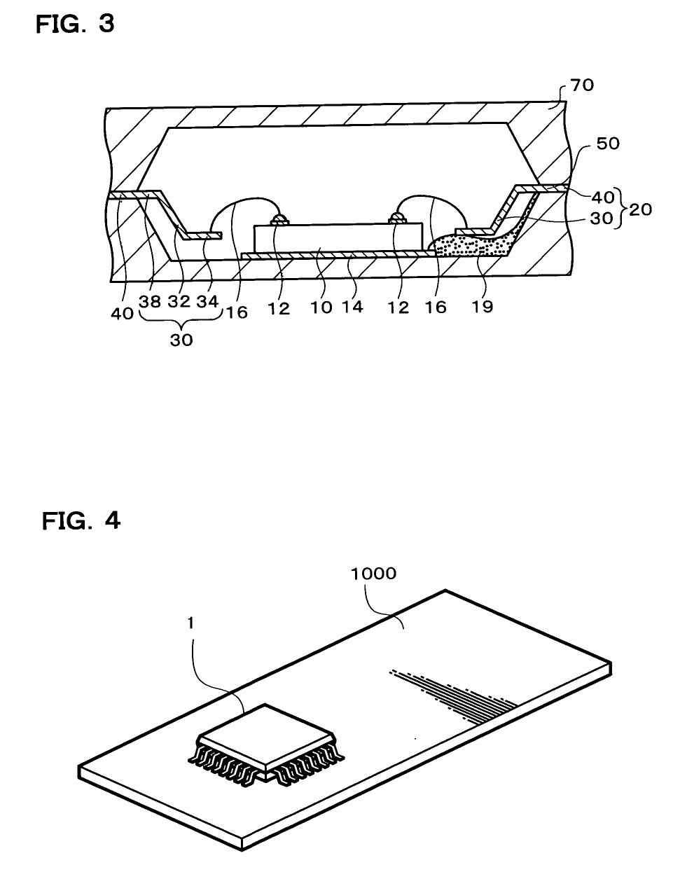

A molding step is then performed. In more detail, the lead frame 50 on which the semiconductor chip 10 is mounted is placed in a mold (die, for example) 70, as shown in FIG. 3. The sealing section 18 is formed by sealing the inner lead 30, the semiconductor chip 10, and the wire 16 with a sealing material (molding resin) 19. A thermosetting resin is generally used as the sealing material 19. However, the sealing material 19 is not limited to the thermosetting resin. In FIG. 3, the lead frame 50 is placed in the mold 70 so that the back surface (surface opposite to the surface on which the semiconductor chip 10 is mounted) of the die pad 14 comes in contact with the inner wall surface of the mold 70. This allows the back surface of the die pad 14 to be exposed, whereby a semiconductor device 1 excelling in moisture resistance and heat sink properties can be manufactured. However, this embodiment is not limited to the above configuration.

A first trimming step is performed. Specifically, the dam bar 56 which connects the leads 20 is cut. The section of the dam bar 56 can be plated in the subsequent electroplating step by cutting the dam bar 56 in advance. In this embodiment, the tab suspension lead 54 is not cut at this stage.

The electroplating step is then performed. Specifically, a metal film of a filler metal (solder, for example) or tin is formed on the lead frame 50 in the area exposed from the sealing section 18. Since the outer leads 40 are electrically connected through the outer frame 52, the outer leads 40 can be electroplated. Since the die pad 14 is electrically connected with the outer frame 52 through the tab suspension lead 54, the die pad 14 can be electroplated. Corrosion resistance is improved by forming a metal film in this manner.

A second trimming step is performed. Specifically, the outer lead 40 is cut from the outer frame 52 and the tab suspension lead 54 is removed. A forming step is performed. Specifically, the outer lead 40 is formed by bending the outer lead 40 into a shape to be easily mounted on a circuit board. The second trimming step and the forming step may be performed at the same time.

A marking step, an inspection step, and the like are optionally performed to obtain the semiconductor device 1.

The inner lead 30 of the semiconductor device according to this embodiment includes the sloping section 32 which slopes upward toward the outside of the semiconductor device. Therefore, the height of the end of the inner lead 30 is decreased. This enables a highly reliable semiconductor device in which the wire 16 rarely comes in contact with an inner lead other than the target inner lead to be provided.

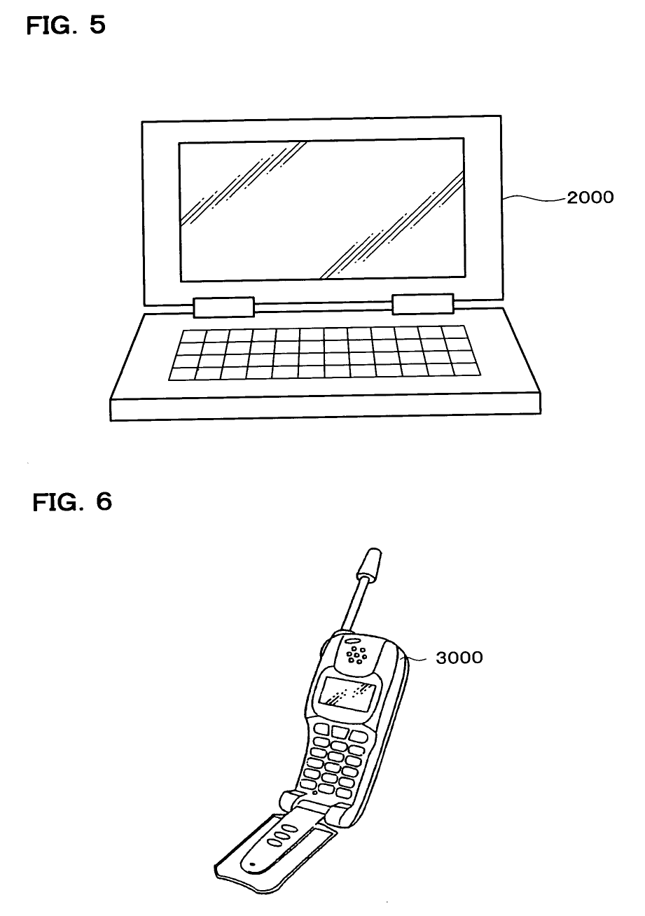

FIG. 4 shows a circuit board 1000 on which the semiconductor device 1 according to this embodiment is mounted. FIGS. 5 and 6 respectively show a notebook-type personal computer 2000 and a portable telephone 3000 as examples of an electronic instrument including the semiconductor device 1.

### Modification Example

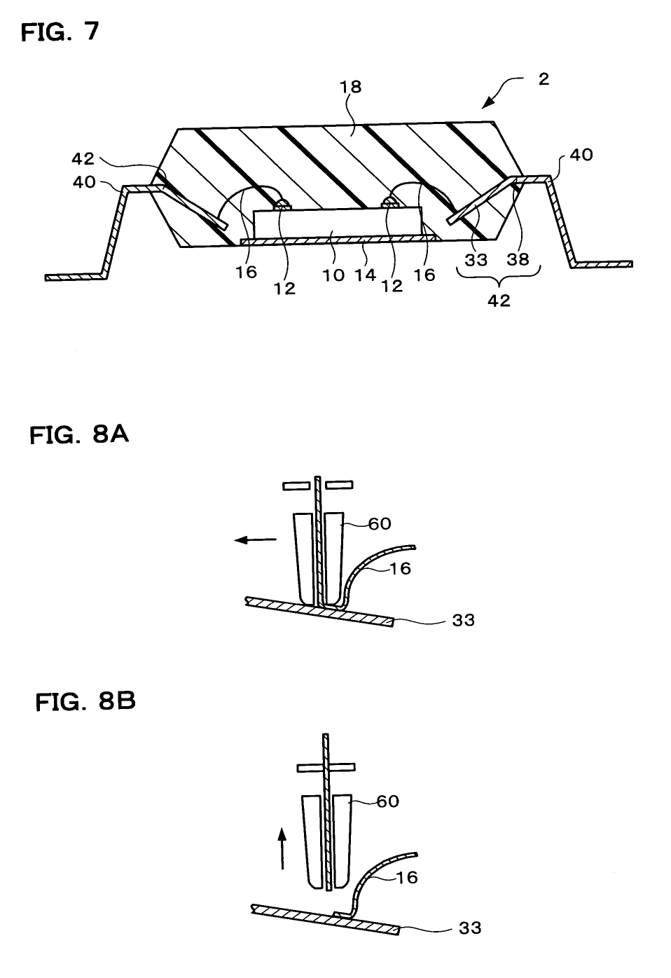

FIGS. 7 to 9 are cross-sectional views showing a semiconductor device according to a modification example of the embodiment to which the present invention is applied.

In the example shown in FIG. 7, an inner lead 42 of a semiconductor device 2 includes a sloping section 33 which slopes upward toward the outside of the semiconductor device, and the part 38 which extends from the outer lead 40 in the horizontal direction. The end of the sloping section 33 may be disposed at a position lower than the electrode 12 of the semiconductor chip 10. The wire 16 may be bonded to the sloping section 33 of the inner lead 42. The wire 16 may be bonded to the sloping section 33 at a position lower than the electrode 12 of the semiconductor chip 10. The details described in the above embodiment may be applied to the other configuration.

The details described in the above embodiment may be applied to the method of manufacturing the semiconductor device shown in FIG. 7 excluding bending the inner lead 42 and bonding the wire 16 to the sloping section 33. The wire 16 may be bonded to the sloping section 33 by using a conventional bonding tool. FIGS. 8A and 8B are views showing a step of bonding the wire 16 to the sloping section 33. In the case of bonding the wire 16 to the sloping section 33, since the sloping section 33 slopes upward toward the outside, the wire 16 can be pressed against the inner lead 42 by applying force to a bonding tool 60 in the horizontal direction (left direction in FIG. 8A). Therefore, it is unnecessary to apply force for pressing the wire 16 against the inner lead 42.

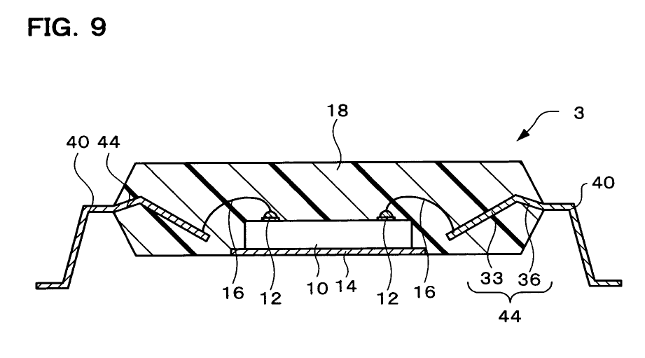

In the example shown in FIG. 9, an inner lead 44 of a semiconductor device 3 includes the sloping section 33 which slopes upward toward the outside of the semiconductor device, and a second sloping section 36 which slopes downward toward the outside of the semiconductor device. The details described in the above embodiment may be applied to the other configuration. The details described in the above embodiment may be applied to the method of manufacturing the semiconductor device shown in FIG. 9 excluding bending the inner lead 44. The second sloping section 36 may be formed by bending the inner lead 44 in the direction opposite to the downset direction of the die pad 14. The inner lead 44 including the sloping section 33 and the second sloping section 36 may be integrally formed by using a jig or the like.

The form of the inner lead of the semiconductor device to which the present invention is applied is not limited to those described above. Specifically, the inner lead may be formed by only the sloping section which slopes upward toward the outside, or the inner lead may be formed by only the sloping section and the end section which extends from the sloping section in the horizontal direction. The second sloping section which slopes downward toward the outside and the part which extends from the outer lead 40 in the horizontal direction may be formed outside the sloping section.

The present invention is not limited to the above-described embodiments, and various modifications can be made. For example, the present invention includes various other configurations substantially the same as the configurations described in the embodiments (in function, method and effect, or in objective and effect, for example). The present invention also includes a configuration in which an unsubstantial portion in the described embodiments is replaced. The present invention also includes a configuration having the same effects as the configurations described in the embodiments, or a configuration able to achieve the same objective. Further, the present invention includes a configuration in which a publicly known technique is added to the configurations in the embodiments.

What is claimed is:

1. A semiconductor device comprising:
an inner lead having a sloping section sloping upward and outward;
a die pad;
a semiconductor chip having an electrode and bonded to the die pad;
a wire electrically connecting the inner lead to the electrode;
a sealing section sealing the inner lead, the semiconductor chip, and the wire; and
an outer lead extending outward from the sealing section.

2. The semiconductor device as defined in claim 1, wherein the wire is bonded to the sloping section.

3. The semiconductor device as defined in claim 1,
wherein the inner lead further has an end section extending inward from a lower end of the sloping section in a horizontal direction.

4. The semiconductor device as defined in claim 3, wherein the wire is bonded to the end section.

5. The semiconductor device as defined in claim 1,
wherein the inner lead further has a second sloping section sloping downward and outward from a higher end of the sloping section.

6. The semiconductor device as defined in claim 1,
wherein the inner lead further has a portion extending in a horizontal direction and connected to the outer lead.

7. The semiconductor device as defined in claim 2,
wherein a bonding position between the wire and the inner lead is lower than the position of the electrode.

8. The semiconductor device as defined in claim 4,
wherein a bonding position between the wire and the inner lead is lower than the position of the electrode.

9. The semiconductor device as defined in claim 1,
wherein a surface of the die pad opposite to the semiconductor chip is exposed from the sealing section.

10. A circuit board on which the semiconductor device as defined in claim 1 is mounted.

11. An electronic instrument comprising the semiconductor device as defined in claim 1.

12. A method of manufacturing a semiconductor device, the method comprising:
forming a sloping section sloping upward and outward by bending an inner lead of a lead frame;
bonding a semiconductor chip having an electrode to a die pad of the lead frame;
electrically connecting the inner lead to the electrode through a wire; and
sealing the inner lead, the semiconductor chip, and the wire.

13. The method of manufacturing a semiconductor device as defined in claim 12,
wherein the wire is bonded to the sloping section.

14. The method of manufacturing a semiconductor device as defined in claim 12, further comprising:
forming an end section extending inward from a lower end of the sloping section in a horizontal direction by bending the inner lead.

15. The method of manufacturing a semiconductor device as defined in claim 14,
wherein the wire is bonded to the end section.

16. The method of manufacturing a semiconductor device as defined in claim 12, further comprising:
forming a second sloping section sloping downward and outward from a higher end of the sloping section by bending the inner lead.

17. The method of manufacturing a semiconductor device as defined in claim 12, further comprising:
forming a portion extending in a horizontal direction and outward from a higher end of the sloping section and bonded to the outer lead of the lead frame.

18. The method of manufacturing a semiconductor device as defined in claim 13,
wherein a bonding position between the wire and the inner lead is made to be lower than the position of the electrode.

19. The method of manufacturing a semiconductor device as defined in claim 15,
wherein a bonding position between the wire and the inner lead is made to be lower than the position of the electrode.

20. The method of manufacturing a semiconductor device as defined in claim 12, further comprising:
exposing a surface of the die pad opposite to the semiconductor chip from the sealing section.
